(19) United States
(12) Patent Application Publication
(10) Pub. No.: US 2023/0064063 A1
(43) Pub. Date: Mar. 2, 2023

(54) MANUFACTURING METHOD FOR SEMICONDUCTOR DEVICE AND SEMICONDUCTOR DEVICE

(71) Applicant: HITACHI ASTEMO, LTD., Hitachinaka-shi, Ibaraki (JP)

(72) Inventors: Kei SUZUKI, Hitachinaka-shi, Ibaraki (JP); Shun KAWANO, Hitachinaka-shi, Ibaraki (JP)

(73) Assignee: HITACHI ASTEMO, LTD., Hitachinaka-shi, Ibaraki (JP)

(21) Appl. No.: 17/785,795

(22) PCT Filed: Nov. 27, 2020
(86) PCT No.: PCT/JP2020/044168

§ 371 Date: Jun. 15, 2022

(30) Foreign Application Priority Data
Dec. 16, 2019 (JP) 2019-226537

(51) Int. Cl. B23K 1/00; B23K 1/20; H01L 23/051; H01L 23/495; H01L 23/00

(52) U.S. Cl. CPC B23K 1/0016; B23K 1/20; H01L 23/051; H01L 23/49513; H01L 23/49575; H01L 24/83; H01L 24/32; H01L 2224/83801; H01L 2224/32245

(57) ABSTRACT

Since the solder 106 temporarily remaining in the first region 301 is in a state of being high in curvature, it is in point contact with the semiconductor element 105 at the vertex of the solder 106. Thereafter, the solder 106 is gradually wetted and spread from the center part to the peripheral part and from the first region 301 to the second region 302 while the semiconductor element 105 is pressed against the solder 106. At this time, since the solder 106 wets and spreads while discharging air, generation of voids can be suppressed.

### TECHNICAL FIELD

The present invention relates to a manufacturing method for a semiconductor device and a semiconductor device.

### BACKGROUND ART

Semiconductor elements are reduced in size, and in solder joint of the semiconductor elements, it is required to prevent generation of voids inside the solder in order to obtain heat dissipation and short-circuit withstanding capability.

PTL 1 describes a technique of wetting and-spreading, to the outside of a frame-like bank portion, a molten solder in a state of being blocked, in processes of providing a recessed region defined by the bank portion opposing to a semiconductor element on a surface of a lead frame, blocking the supplied molten solder by the bank portion, and mounting the semiconductor element.

### CITATION LIST

### Patent Literature

PTL 1: JP 2015-109294 A

### SUMMARY OF INVENTION

### Technical Problem

The technique described in PTL 1 has not been able to sufficiently prevent generation of voids inside the solder and solder overflow.

### Solution to Problem

A manufacturing method for a semiconductor device according to the present invention includes: a first process of forming, on a first surface of a lead frame, a first region and a second region that surrounds an outer periphery of the first region and is relatively lower in wettability and spreadability of solder than the first region; a second process of disposing the solder on the first region of the lead frame; and a third process of pressing a semiconductor element against the solder disposed on the first region to wet and spread the solder onto the second region.

A semiconductor device according to the present invention includes: a semiconductor element; a lead frame including a first surface provided with a first region and a second region that surrounds an outer periphery of the first region and is relatively lower in wettability and spreadability of solder than the first region; and solder that joins between a semiconductor element and the lead frame in a state of being wetted and spread across the first region and the second region of the lead frame, in which an outer peripheral edge of a joint region of the solder on the lead frame side substantially coincides with an outer peripheral edge of the second region.

### Advantageous Effects of Invention

According to the present invention, it is possible to prevent generation of voids and solder overflow.

### BRIEF DESCRIPTION OF DRAWINGS

FIG. 1 is an exploded perspective view of a semiconductor device.

FIG. 2 is an exploded perspective view of a main part of the semiconductor device.

FIG. 3 is a perspective view of a lead frame.

FIG. 4 is a view explaining a first process of a manufacturing method for the semiconductor device.

FIGS. 5(A) and (B) are views explaining a second process of the manufacturing method for the semiconductor device.

FIGS. 6(A) and (B) are views explaining a third process of the manufacturing method for the semiconductor device.

FIGS. 7(A), (B), and (C) are views illustrating hatching examples 1, 2, and 3 of the lead frame.

FIGS. 8(A), (B), and (C) are views illustrating hatching examples 4, 5, and 6 of the lead frame.

FIGS. 9(A), (B), and (C) are views illustrating hatching examples 7, 8, and 9 of the lead frame.

FIGS. 10(A), (B), and (C) are views illustrating hatching examples 10, 11, and 12 of the lead frame.

FIGS. 11(A), (B), and (C) are views illustrating wetting and spreading of solder by a hatching example 13 of the lead frame.

### DESCRIPTION OF EMBODIMENTS

An embodiment of the present invention will be described below with reference to the drawings. The following description and drawings are illustrative of the present invention and are omitted and simplified as appropriate for a clearer description. The present invention can also be carried out in various other forms. Unless otherwise specified, each component may be singular or plural.

For the purpose of facilitating understanding of the invention, the position, size, shape, range, and the like, of each component illustrated in the drawings do not necessarily represent the actual position, size, shape, range, and the like. Therefore, the present invention is not necessarily limited to the position, size, shape, range, and the like, disclosed in the drawings.

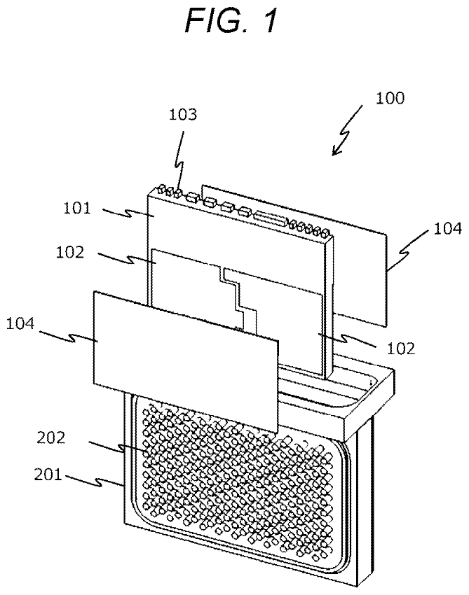

FIG. 1 is an exploded perspective view of a semiconductor device 100 according to the present embodiment.

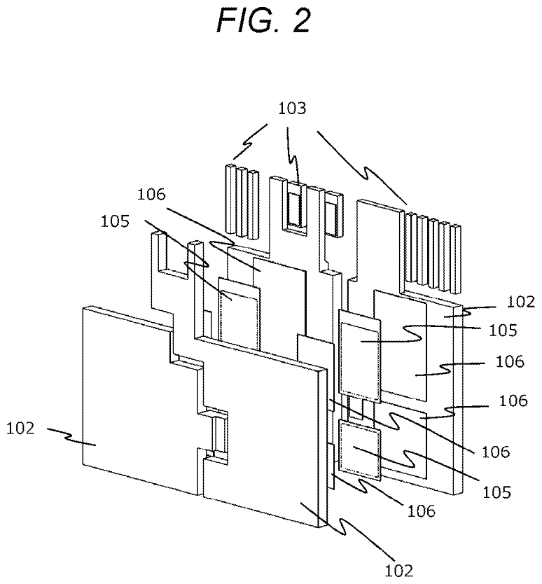

As illustrated in FIG. 1, the semiconductor device 100 includes, inside therein, mold resin 101 for sealing a semiconductor element 105 (see FIG. 2). Both surfaces of the mold resin 101 are provided with a lead frame 102 connected to the semiconductor element 105 by solder 106 (see FIG. 2). A plurality of connection terminals 103 electrically connected to the semiconductor element 105 protrude from the upper part of the mold resin 101. An insulation sheet 104 is disposed on both surfaces of the lead frame 102.

After the insulation sheet 104 is bonded to both surfaces of the lead frame 102, the semiconductor device 100 is housed in the case 201 and sealed with resin. Both surfaces of the case 201 are provided with a plurality of heat dissipation fins 202, and a refrigerant not illustrated flows between the heat dissipation fins 202 to cool heat generated from the semiconductor element 105.

FIG. 2 is an exploded perspective view of a main part of the semiconductor device 100.

In FIG. 2, the mold resin 101 is not illustrated. In the present embodiment, an example in which an insulated gate bipolar transistor (IGBT) and a diode chip are provided as the semiconductor element 105 will be described. Note that the semiconductor element 105 is not limited to the IGBT, and may be a MOSFET or SiC. FIG. 2 illustrates an example in which one IGBT and one diode are arranged in one arm, but any number of semiconductor elements 105 may be mounted.

As illustrated in FIG. 2, the semiconductor element 105 is connected to the lead frame 102 via the solder 106 on both surfaces thereof. The present embodiment is characterized in connection between the semiconductor element 105 and the lead frame 102 by the solder 106 as described later.

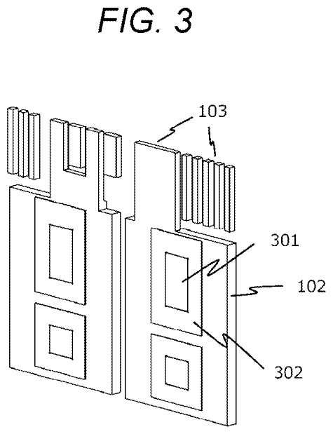

FIG. 3 is a perspective view of the lead frame 102. As illustrated in FIG. 3, the lead frame 102 is provided with a region including a first region 301 and a second region 302 corresponding to one semiconductor element 105. That is, the first surface of the lead frame 102 is provided with the first region 301 and the second region 302, which surrounds the outer periphery of the first region 301 and is relatively lower in wettability and spreadability of the solder 106 than the first region 301. FIG. 3 illustrates four regions including the first region 301 and the second region 302. Each region corresponds to two IGBTs and two diode chips as the semiconductor element 105.

<First Process: Manufacturing Method for Semiconductor Device 100>

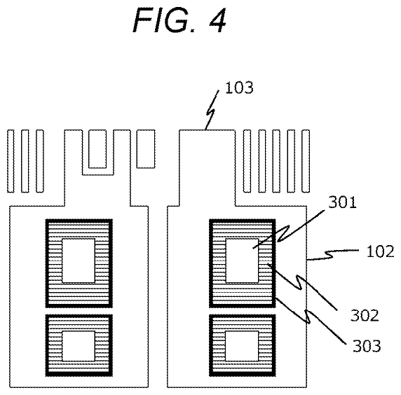

The first process of the manufacturing method for the semiconductor device 100 will be described. FIG. 4 is a front view of the lead frame 102.

The lead frame 102 is made of copper (Cu). The lead frame 102 is surface-treated with nickel-palladium (NiPd) or nickel plating. In order to separate the first region 301 and the second region 302 from each other, the surface of the lead frame 102 may be subjected to a baking treatment or the like in advance to remove contained moisture or the like.

When the lead frame 102 is surface-treated with nickel-palladium, the second region 302 is subjected to laser machining. That is, the second region 302 is irradiated with a laser to remove palladium (Pd) on the surface, thereby exposing the nickel (Ni) surface on the surface. This suppresses the solder 106 from wetting and spreading to the second region 302.

When the lead frame 102 is surface-treated with nickel plating, the first region 301 is subjected to laser machining. That is, the first region 301 is irradiated with a laser to flatten the roughened nickel surface or expose copper of base metal. This makes the solder 106 easily wet to the first region 301.

In the first process, as presented in an example described below, various hatching is performed by laser machining to form a portion where the solder 106 is likely to wet and spread and a portion where the solder 106 is unlikely to wet and spread, thereby determining the way the solder 106 wets and spreads, the direction in which the solder 106 flows, and a flow speed. That is, in the first process, the first surface of the lead frame is provided with the first region 301 and the second region 302, which surrounds the outer periphery of the first region 301 and is relatively lower in wettability and spreadability of the solder 106 than the first region 301. Specifically, at least one of the first region 301 and the second region 302 is hatched by laser machining such that the second region 302 becomes relatively low in wettability and spreadability of the solder 106. The density, interval, and direction of hatching of the first region 301 and the second region 302 are selected by a relative difference between the wettability and spreadability of the solder 106 on the surface and the wettability and spreadability of the solder 106 subjected to laser machining on the surface. Note that when the outer periphery of the first region 301 is framed by laser machining or the like, the solder 106 easily remains in the first region 301.

Advantages that the solder 106 easily wets and spreads in the first region 301 will be described.

When the solder 106 is disposed on the lead frame 102 using a solder transfer tool 401 described later, a transfer amount of the solder 106 (amount of the solder 106) to be transferred to the lead frame 102 is stabilized by setting the first region 301 to a region having good wetting and spreading. Specifically, the solder 106 is easily separated from the solder transfer tool 401, and the amount of the solder 106 is stabilized. The solder 106 wets and spreads uniformly over the entire inner surface of the first region 301. The same applies to the case where the solder 106 is dropped with a syringe.

Then, when the solder 106 wets and spreads in the first region 301, and then the solder 106 wets and spreads in the second region 302, the solder can be uniformly wetted and spread in the second region 302, and inclusion of air is prevented when the solder 106 wets and spreads in the second region 302. The solder 106 having wetted and spread in the second region 302 simultaneously reaches the four sides of an outer peripheral edge 303 of the second region 302, whereby the solder 106 is not locally crushed. Therefore, the solder 106 hardly overflows from the outer peripheral edge 303. The outer peripheral edge 303 of the second region 302 forms a barrier on the surface by oxidation or the like. The shape of the outer peripheral edge 303 may be concave or convex with respect to the surface. This suppresses the solder 106 from overflowing from the solder region (the first region 301 and the second region 302).

<Second Process: Manufacturing Method for Semiconductor Device 100>

The second process of the manufacturing method for the semiconductor device 100 is a process of disposing the solder 106 on the first region 301 of the lead frame 102.

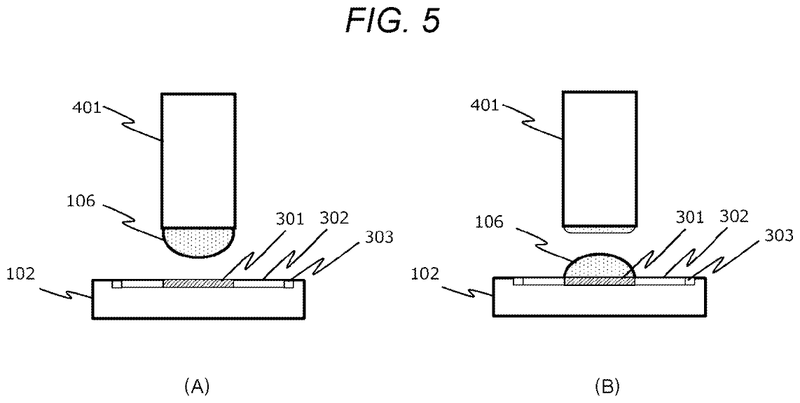

FIGS. 5(A) and 5(B) are views explaining the second process. FIG. 5(A) illustrates a state immediately before the solder 106 is transferred from the solder transfer tool 401 to the lead frame 102. FIG. 5(B) illustrates a state immediately after the solder 106 is transferred from the solder transfer tool 401 to the lead frame 102.

First, the solder transfer tool 401 is immersed in a solder bath, and the solder 106 is attached to the solder transfer tool 401 as illustrated in FIG. 5(A). Then, the solder transfer tool 401 is disposed at a position opposing the center part of the first region 301 of the lead frame 102. The shape of the solder transfer tool 401 is discretionary, and may be a rectangle (round chamfering may be provided) or a circle.

Next, as illustrated in FIG. 5(B), the solder transfer tool 401 attached with the solder 106 is moved downward and the solder 106 is transferred to the center part of the first region 301. The solder 106 wets and spreads to the first region 301. In order to wet and spread the solder 106 to the first region 301, the solder transfer tool 401 may be moved in parallel vertically and horizontally when the solder 106 is transferred by the solder transfer tool 401.

The first region 301 is a region where the solder 106 is relatively better in wettability and spreadability than the second region 302, and causes the solder 106 to temporarily remain in a narrow region to increase the curvature of the solder 106. The solder 106 remaining in the first region 301 is maintained in a high curvature state. At this time, the curvature of the solder 106 remaining in the first region 301 is preferably as high as possible. This is because the solder 106 and the semiconductor element 105 are desirably in point contact at a vertex of the solder 106 in the next third process.

Even if the solder 106 flows out from the first region 301, as long as the solder does not spread over the entire second region 302, the solder 106 can maintain the curvature, and in the next third process, the solder 106 can be crushed while discharging air, whereby an effect of reducing voids can be expected. When the solder 106 is crushed via the semiconductor element 105, the solder 106 straddles the boundary between the first region 301 and the second region 302. The curvature only needs to be maintained even if the solder 106 does not spread over the entire first region 301.

<Third Process: Manufacturing Method for Semiconductor Device 100>

The third process of the manufacturing method for the semiconductor device 100 is a process of pressing the semiconductor element 105 against the solder 106 disposed on the first region 301 to wet and spread the solder 106 onto the second region 302.

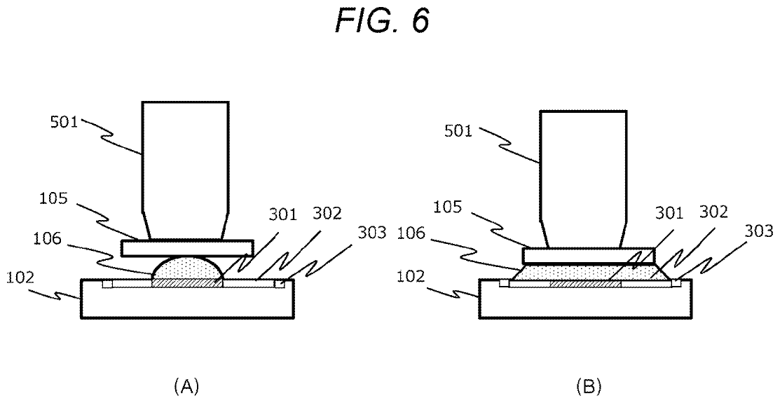

FIGS. 6(A) and 6(B) are views explaining the third process. FIG. 6(A) illustrates a state in which the semiconductor element 105 sucked by a chip suction collet 501 is positioned at the vertex of the solder 106. FIG. 6(B) illustrates a state in which the semiconductor element 105 is pressed by the chip suction collet 501 to wet and spread the solder 106 onto the second region 302.

As illustrated in FIG. 6(A), since the solder 106 temporarily remaining in the first region 301 is in a state of being high in curvature, it is in point contact with the semiconductor element 105 at the vertex of the solder 106. Thereafter, the solder 106 is gradually wetted and spread from the center part to the peripheral part and from the first region 301 to the second region 302 while the semiconductor element 105 is pressed against the solder 106. At this time, since the solder 106 wets and spreads while discharging air, generation of voids can be suppressed.

As illustrated in FIG. 6(B), the semiconductor element 105 is connected to the lead frame 102 in the first region 301 and the second region 302 via the solder 106. The solder 106 having wetted and spread in the second region 302 remains at the outer peripheral edge 303, and the solder 106 does not overflow. In the second region 302, since the solder 106 is less likely to wet and spread, the solder 106 is suppressed from flowing, and the solder 106 is less likely to overflow.

The semiconductor device 100 manufactured through the above process includes the semiconductor element 105, the lead frame 102, and the solder 106. The lead frame 102 is provided with the first region 301 and the second region 302. The second region 302 surrounds the outer periphery of the first region 301, and is relatively lower in wettability and spreadability of the solder 106 than the first region 301. The solder 106 joins the semiconductor element 105 and the lead frame 102 in a state of being wetted and spread across the first region 301 and the second region 302 of the lead frame 102. The outer peripheral edge of the joint region of the solder 106 on the lead frame 102 side substantially coincides with the outer peripheral edge 303 of the second region 302. The outer peripheral edge 303 of the second region is a third region that regulates wetting and spreading of the solder 106.

Next, an example of hatching by laser machining applied to the first region 301 or the second region 302 of the lead frame 102 in the above-described first process will be described. As described earlier, a portion where the solder 106 is likely to wet and spread and a portion where the solder 106 is unlikely to wet and spread are formed by hatching, whereby it is possible to determine the way the solder 106 wets and spreads, the direction in which the solder 106 flows, and a flow speed.

In the following examples 1 to 13, a case where the lead frame 102 is surface-treated with nickel-palladium will be described. When the lead frame 102 is surface-treated with nickel plating, hatching in the first region 301 and the second region 302 is reverse of that in the examples 1 to 13 in the case of nickel-palladium. In the examples 1 to 13 of each hatching, the first region 301 and the second region 302 may be combined. The examples 1 to 13 of each hatching will be described only on the lead frame 102 side corresponding to the IGBT, but hatching is similarly formed on the lead frame 102 side corresponding to the diode. In this case, the lead frame 102 side corresponding to the IGBT and the lead frame 102 side corresponding to the diode do not need to have the same hatching.

(Hatching Example 1 of Lead Frame 102)

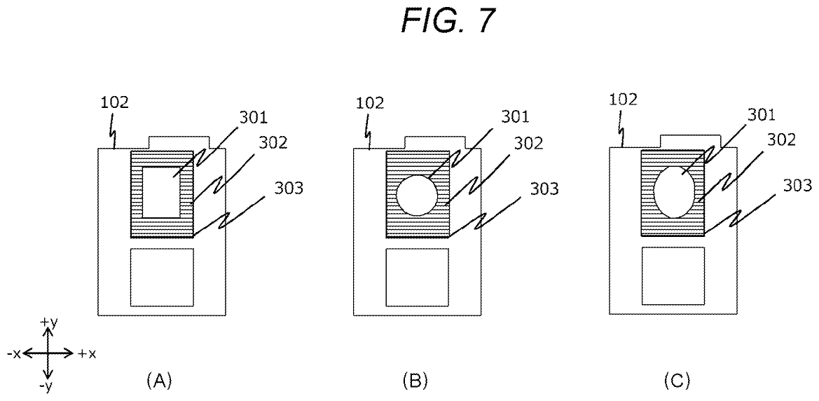

FIG. 7(A) is a view illustrating the hatching example 1 of the lead frame 102. In this example 1, the outer peripheral shape of the first region 301 and the outer peripheral shape of the second region 302 are formed to be similar to each other. By the similarity, the distance of wetting and spreading from the outer periphery of the first region 301 to the outer periphery of the second region becomes constant, and the solder 106 simultaneously reaches the outer peripheral edge 303. Therefore, the solder 106 becomes less likely to locally overflow from the outer peripheral edge 303. Round chamfering may be provided to corner portions of the outer peripheral part and the outer peripheral edge 303 of the first region 301 to suppress the solder 106 from overflowing at the corner portions.

(Hatching Example 2 of Lead Frame 102)

FIG. 7(B) is a view illustrating the hatching example 2 of the lead frame 102. In this example 2, the outer peripheral shape of the first region 301 is formed in a circular shape. Due to the circular shape, the surface tension of the solder 106 remaining in the first region 301 is stabilized, the curvature of the solder 106 can be maintained, and the solder 106 easily remains in the first region 301.

(Hatching Example 3 of Lead Frame 102)

FIG. 7(C) is a view illustrating the hatching example 3 of the lead frame 102. In this example 3, the outer peripheral shape of the first region 301 is formed in an elliptical shape. Due to the elliptical shape, the surface tension of the solder 106 remaining in the first region 301 is stabilized, the curvature of the solder 106 can be maintained, and the solder 106 easily remains in the first region 301. Furthermore, in a case where the semiconductor element 105 has a rectangular shape, by forming the major axis of the elliptical shape in the y direction in the figure in accordance with the long side direction (y direction in the figure), the solder 106 can be uniformly wetted and spread.

(Hatching Example 4 of Lead Frame 102)

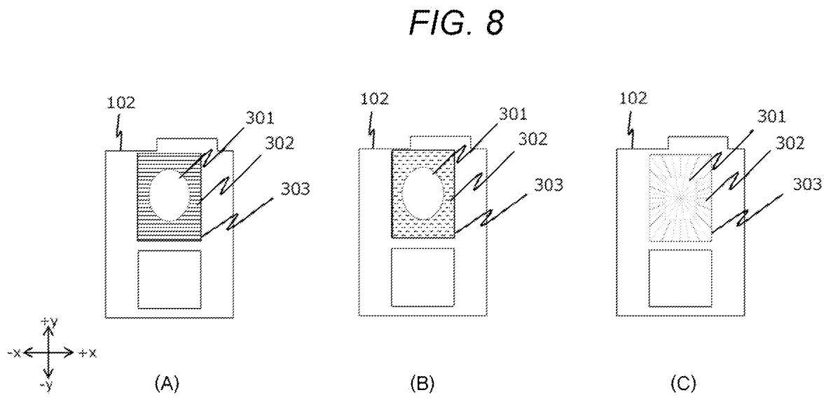

FIG. 8(A) is a view illustrating the hatching example 4 of the lead frame 102. In this example 4, the boundary between the first region 301 and the second region 302 is formed in a dotted line or a broken line. In order to align the direction of the wettability and spreadability, the second region 302 is hatched with a straight line in the x direction in the figure.

Even when the boundary between the first region 301 and the second region 302 is a dotted line or a broken line, the solder 106 temporarily remains in the first region 301 due to the surface tension of the solder 106. When the solder 106 is crushed by the semiconductor element 105, the solder 106 easily flows to the second region 302, and the solder 106 can be prevented from being locally wetted from the first region 301.

(Hatching Example 5 of Lead Frame 102)

FIG. 8(B) is a view illustrating the hatching example 5 of the lead frame 102. In this example 5, the boundary between the first region 301 and the second region 302 is formed in a dotted line or a broken line. The second region 302 is hatched with a broken line or a dotted line in the x direction in the figure in order to suppress the wettability and spreadability and change the direction.

Similarly to the example 4, even when the boundary between the first region 301 and the second region 302 is a dotted line or a broken line, the solder 106 temporarily remains in the first region 301 due to the surface tension of the solder 106. When the solder 106 is crushed by the semiconductor element 105, the solder 106 easily flows to the second region 302, and the solder 106 can be prevented from being locally wetted from the first region 301. By hatching the second region 302 with a broken line or a dotted line, it is possible to suppress the wettability and spreadability of the solder 106 and define the direction.

(Hatching Example 6 of Lead Frame 102)

FIG. 8(C) is a view illustrating the hatching example 6 of the lead frame 102. In this example 6, hatching by laser machining is formed radially from the center of the first region 301. In this case, the density of hatching is changed between the first region 301 and the second region 302. In this example 6, the density of hatching in the second region 302 is increased.

With radially formed hatching, the solder 106 wets and spreads radially and smoothly from the center of the first region 301. By increasing the hatching density of the second region 302, first, the solder 106 remains in the first region 301, and then when the solder 106 is crushed by the semiconductor element 105, the solder 106 wets and spreads to the second region 302.

(Hatching Example 7 of Lead Frame 102)

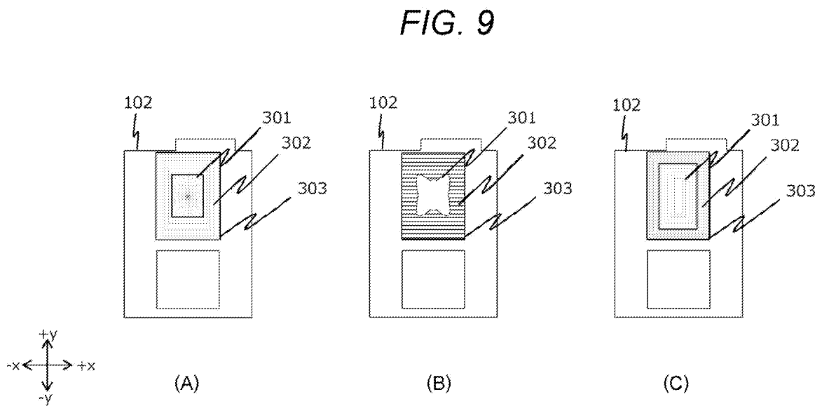

FIG. 9(A) is a view illustrating the hatching example 7 of the lead frame 102. In this example 7, hatching by laser machining is formed radially from the center of the first region 301. The second region 302 is hatched by laser machining formed in a plurality of similar linear shapes similar to the outer shape (quadrangle) of the second region 302.

The solder 106 wets and spreads in the first region 301 by radial hatching, but the second region 302 is hatched in a quadrangle shape to suppress fluidity of the solder 106 and prevent the solder 106 from overflowing from the outer peripheral edge 303.

(Hatching Example 8 of Lead Frame 102)

FIG. 9(B) is a view illustrating the hatching example 8 of the lead frame 102. In this example 8, the outer peripheral shape of the first region 301 is formed in a curved shape. In order to align the direction of the wettability and spreadability in the second region 302, linear hatching is performed in the x direction in the figure.

Due to the curved shape with the protruding four corners of the first region 301, the solder 106 wets and spreads from the first region 301 to the four corners of the second region 302. The first region 301 formed in a curved shape makes it possible to control the position where the solder 106 wets and spreads, and reduce shrinkage cavities at the wraparound boundary of the solder 106.

(Hatching Example 9 of Lead Frame 102) FIG. 9(C) is a view illustrating the hatching example 9 of the lead frame 102. In this example 9, the first region 301 and the second region 302 are hatched by laser machining formed in a plurality of similar linear shapes similar to the outer shape (quadrangle). Then, the density of hatching is changed between the first region 301 and the second region 302. In this example 9, the density of hatching in the second region 302 is increased.

Since the density of hatching in the first region 301 is lower than that in the second region 302, the solder 106 wets and spreads. On the other hand, since the second region 302 is hatched with high density and hatched in a quadrangle shape, the fluidity of the solder 106 is suppressed, and the solder 106 is prevented from overflowing from the outer peripheral edge 303. By changing the density of the first region 301 and the second region 302, it is possible to define the way of wetting and spreading and the fluidity.

(Hatching Example 10 of Lead Frame 102)

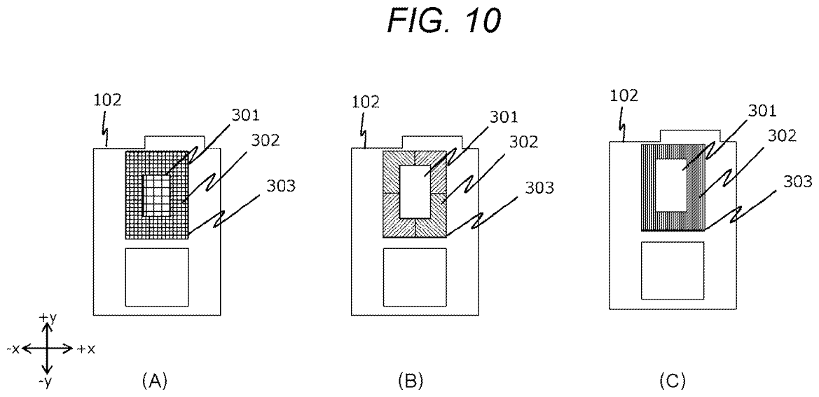

FIG. 10(A) is a view illustrating the hatching example 10 of the lead frame 102. In this example 10, the first region 301 and the second region 302 are hatched by laser machining formed in a lattice shape in the x-y direction (horizontal line shape and vertical line shape). Then, the density of hatching is changed between the first region 301 and the second region 302. In this example 10, the density of hatching in the second region 302 is increased.

Since the density of hatching in the first region 301 is lower than that in the second region 302, the solder 106 wets and spreads in the first region 301. On the other hand, since the second region 302 is hatched with high density and hatched in a quadrangle shape, the fluidity of the solder 106 is suppressed, and the solder 106 is prevented from overflowing from the outer peripheral edge 303. By changing the density of the first region 301 and the second region 302, it is possible to define the way of wetting and spreading and the fluidity. The lattice shape of hatching is not limited to the x-y direction, and may be a lattice shape rotated by 45° with respect to the x-y direction, for example.

(Hatching Example 11 of Lead Frame 102)

FIG. 10(B) is a view illustrating the hatching example 11 of the lead frame 102. In this example 11, the second region 302 is divided into four regions including each of the four corners, and each region is hatched by laser machining with combination of the x direction+45°/−45°. In each region, the direction of the hatching is a direction toward each of the four corners of the second region 302.

The solder 106 can be smoothly wetted and spread toward each of the four corners in the second region 302, and shrinkage cavities at the wraparound boundary of the solder 106 are reduced. Note that similar hatching may be applied also to the first region 301. In this case, the density of hatching in the second region 302 is increased.

(Hatching Example 12 of Lead Frame 102) FIG. 10(C) is a view illustrating the hatching example 12 of the lead frame 102. In this example 12, hatching by laser machining is applied to the second region 302 in a vertical line shape, which is the y direction.

In a case where the semiconductor element 105 has a rectangular shape, by forming hatching in the y direction in accordance with the long side direction (y direction in the figure), the solder 106 can be wetted and spread in the y direction. Note that hatching may be applied in a horizontal line shape, which is the x direction. In this case, the solder 106 can be uniformly wetted and spread in the x direction.

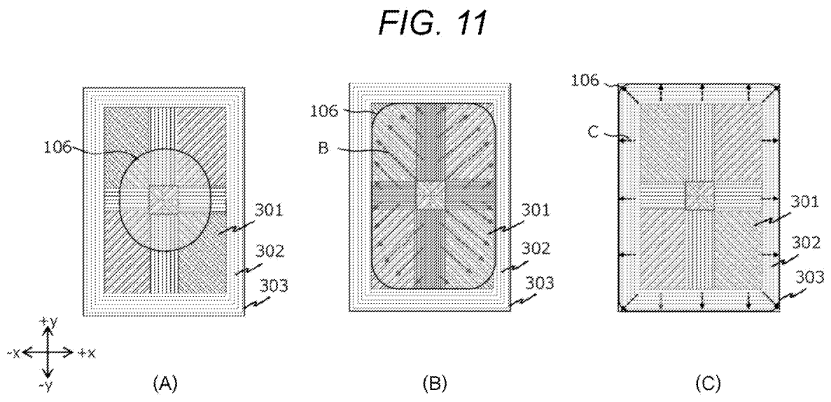

(Hatching Example 13 of Lead Frame 102) FIGS. 11(A) to 11(C) are views illustrating wetting and spreading of the solder 106 on the hatched lead frame 102.

The hatching illustrated in FIGS. 11(A) to 11(C) is an example. In the hatching of the first region 301, the first region 301 is divided into four regions including each of the four corners, and each region is hatched by laser machining with combination of the x direction+45°/−45°. Furthermore, band-shaped regions are provided in the x direction and the y direction, and the region in the x direction is hatched in the x direction by laser machining, and the region in the y direction is hatched in the y direction by laser machining. Furthermore, in the center part of the first region 301, the center part is divided into four regions including each of the four corners, and each region is hatched by laser machining with combination of the x direction+45°/−45°. The second region 302 is hatched by laser machining formed in a plurality of similar linear shapes similar to the outer shape (quadrangle).

FIG. 11(A) illustrates a state in which the solder 106 is disposed in the center part of the first region 301. As illustrated in FIG. 11(A), when the solder 106 of the solder transfer tool 401 comes into contact with the center part of the first region 301, the solder 106 wets and spreads while being distributed in the xy direction and the ±45° direction by hatching applied to the first region 301.

FIG. 11(B) illustrates a state in which the solder 106 wets and spreads in the first region 301. As illustrated in FIG. 11(B), the solder 106 proceeds in the xy direction along a line hatched in the xy direction in the figure, the solder 106 wets and spreads along a line hatched in the ±45° direction with respect to the xy direction (arrow B in the figure), and the solder 106 wets and spreads to the entire first region 301.

FIG. 11(C) illustrates a state in which the solder 106 is wetted and spread by pressing the semiconductor element 105. As illustrated in FIG. 11(C), by pressing the semiconductor element 105 against the solder 106, the solder 106 overflows from the first region 301. At this time, in the second region 302, wetting and spreading in the outer peripheral direction is suppressed by the quadrangle hatching, and the solder 106 becomes difficult to flow. Then, the solder 106 is blocked by the outer peripheral edge 303 to prevent overflowing.

According to the embodiment described above, the following operational effects can be obtained.

(1) The manufacturing method for the semiconductor device 100 includes: the first process of forming, on the first surface of the lead frame 102, the first region 301 and the second region 302 that surrounds an outer periphery of the first region 301 and is relatively lower in wettability and spreadability of the solder 106 than the first region 301; the second process of disposing the solder 106 on the first region 301 of the lead frame 102; and the third process of pressing the semiconductor element 105 against the solder 106 disposed on the first region 301 to wet and spread the solder 106 onto the second region 302. This makes it possible to prevent generation of voids and solder overflow.

(2) The semiconductor device 100 includes: the semiconductor element 105; the lead frame 102 including the first surface provided with the first region 301 and the second region 302 that surrounds the outer periphery of the first region 301 and is relatively lower in wettability and spreadability of the solder 106 than the first region 301; and the solder 106 that joins between the semiconductor element 105 and the lead frame 102 in a state of being wetted and spread across the first region 301 and the second region 302 of the lead frame 102, in which the outer peripheral edge of a joint region of the solder 106 on the lead frame 102 side substantially coincides with the outer peripheral edge 303 of the second region 302.

This makes it possible to prevent generation of voids and solder overflow.

The present invention is not limited to the above embodiment, and other forms conceivable within the scope of the technical idea of the present invention are also included within the scope of the present invention as long as the features of the present invention are not impaired. The examples described in the above embodiment may be combined.

### REFERENCE SIGNS LIST

100 semiconductor device
101 mold resin
102 lead frame
103 connection terminal
104 insulation sheet
105 semiconductor element
106 solder
201 case
202 heat dissipation fin
301 first region
302 second region
303 outer peripheral edge
401 solder transfer tool
501 chip suction collet

1. A manufacturing method for a semiconductor device, comprising:
a first process of forming, on a first surface of a lead frame, a first region and a second region that surrounds an outer periphery of the first region and is relatively lower in wettability and spreadability of solder than the first region;
a second process of disposing the solder on the first region of the lead frame; and
a third process of pressing a semiconductor element against the solder disposed on the first region to wet and spread the solder onto the second region.

2. The manufacturing method for a semiconductor device according to claim 1, wherein in the first process, at least one of the first region and the second region is formed by laser machining.

3. The manufacturing method for a semiconductor device according to claim 2, wherein in the first process, the second region is formed by the laser machining on the lead frame on which surface treatment with nickel-palladium is formed on the first surface.

4. The manufacturing method for a semiconductor device according to claim 2, wherein in the first process, the first region is formed by the laser machining on the lead frame on which surface treatment with nickel plating is formed on the first surface.

5. The manufacturing method for a semiconductor device according to claim 2, wherein in the first process, an outer peripheral shape of the first region and an outer peripheral shape of the second region are formed to be similar to each other.

6. The manufacturing method for a semiconductor device according to claim 2, wherein in the first process, an outer peripheral shape of the first region is formed into a circular shape or an elliptical shape.

7. The manufacturing method for a semiconductor device according to claim 2, wherein in the first process, an outer peripheral shape of the first region is formed into a curved shape.

8. The manufacturing method for a semiconductor device according to claim 2, wherein in the first process, a boundary between the first region and the second region is formed in a dotted line or a broken line.

9. The manufacturing method for a semiconductor device according to claim 2, wherein in the first process, the first region and the second region are formed by applying hatching by the laser machining.

10. The manufacturing method for a semiconductor device according to claim 9, wherein in the first process, a density of the hatching by the laser machining is changed between the first region and the second region.

11. The manufacturing method for a semiconductor device according to claim 9, wherein in the first process, the hatching by the laser machining is formed radially from a center of the first region.

12. The manufacturing method for a semiconductor device according to claim 9, wherein in the first process, the hatching by the laser machining is formed in a horizontal line shape or/and a vertical line shape.

13. The manufacturing method for a semiconductor device according to claim 9, wherein in the first process, the hatching by the laser machining is formed in a similar linear shape similar to an outer shape of the second region.

14. A semiconductor device, comprising:
a semiconductor element;
a lead frame including a first surface provided with a first region and a second region that surrounds an outer periphery of the first region and is relatively lower in wettability and spreadability of solder than the first region; and
solder that joins between a semiconductor element and the lead frame in a state of being wetted and spread across the first region and the second region of the lead frame, wherein
an outer peripheral edge of a joint region of the solder on the lead frame side substantially coincides with an outer peripheral edge of the second region.

15. The semiconductor device according to claim 14, wherein an outer peripheral edge of the second region is a third region that regulates wetting and spreading of the solder.
